(19) United States
(12) Patent Application Publication
(10) Pub. No.: US 2026/0304688 A1
(43) Pub. Date: Oct. 1, 2026

(54) COOLING OF ELECTRONIC COMPONENTS IN ELECTRONICS SERVERS

(71) Applicant: AMD Design, LLC, Wilmington, DE (US)

(72) Inventors: Pruthvik RAGHUPATHI, Seattle, WA (US); Sunilkumar PINNU, Jersey City, NJ (US); Sruti CHIGULLAPALLI, Seattle, WA (US)

(73) Assignee: AMD Design, LLC, Wilmington, DE (US)

(21) Appl. No.: 19/095,630

(22) Filed: Mar. 31, 2025

(51) Int. Cl. H05K 7/20

(52) U.S. Cl. CPC H05K 7/20254; H05K 7/20154; H05K 7/20263; H05K 7/20409; H05K 7/20509; H05K 7/20727; H05K 7/20772

(57) ABSTRACT

A system, apparatus, and method for cooling multiple electronics components that includes a plurality of heat spreaders where each heat spreader includes a first plate and a second plate. The first plate has a first body portion configured to form a thermal transfer relationship with a first side of a first electronic component. The second plate has a second body portion configured to form a thermal transfer relationship with a second side of the first electronic component. The heat spreader has an extending member extending to and overlapping with a portion of a cold plate arranged to cool a second electronics component.

### FIELD

This disclosure is directed to cooling of electronic components in electronics servers, including for example hybrid cooling of Dual Inline Memory Modules (DIMMs) with other electronic components, for example, Solid State Drives (SSDs) and the like.

### BACKGROUND

A plurality of electronic components (e.g., hard drives, integrated circuits, networking equipment, etc.) are often assembled on printed circuit boards assembled in electronic servers, e.g., artificial intelligence (AI) servers. The density and packing of electronic components in these servers continue to increase, and in addition to higher powered GPUs, the power consumption of other electronic components in the servers (CPU, memory, NIC cards, etc.) are also increasing. The increasing density of electronics components in servers, and the increasingly greater power consumption by these electronic components is generating increasingly greater heat in electronics servers. Cooling of the electronic components in these electronics servers is also becoming increasingly important and complex. While liquid cooling of larger components, for example the CPU and GPU are relatively common, cooling smaller components, for example the NIC card, DIMM memory and storage, comes with its own set of challenges.

Space constraints in the servers make very difficult or prevent individually served liquid coolant loops to each of the electronic components, and as the number of components that are in a single coolant loop increase, the complexity of the loop increases, and this leads to flow balancing issues while configuring the coolant loop and serviceability issues during operation. With the power of newer generation DIMMs continuing to increase, effectively cooling all the electronic components, for example, the DIMMs, is a challenge. There is a need for an effective method to move (e.g., remove) heat from smaller devices with limited space to improve the efficiency of cooling, e.g., air cooling, in electronics servers.

### SUMMARY

A system, product, and method are disclosed to cool two adjacent electronic components, e.g., DIMMs and Solid State Drives (SSDs), using a cooling system such as a hybrid cooling system. In an embodiment the cooling system includes a combination of a cold plate and a heat spreader. In one or more configurations the heat spreader is configured to be in a thermal transfer relationship with one or more first electronic components and in a thermal relationship with a cold plate. In one or more arrangements, the cold plate is in a further thermal relationship with one or more second electronic components.

In an embodiment, an apparatus is disclosed, the apparatus including: a body formed of thermally conductive material configured to be in at least one of a first thermal group consisting of: in contact with, in a thermally conductive relationship with, and combinations thereof with a first electronic component. The apparatus in an arrangement further includes an extending member projecting from the body configured to extend to and overlap with a portion of a cold plate arranged to cool a second electronics component, the extending member further configured to be in at least one of a second thermal group consisting of: contact with, in a thermally conductive relationship with, and combinations thereof with the cold plate. The apparatus according to an embodiment includes a first plate and a second plate, wherein, the first plate has a first body portion configured as a relative thin plate forming a first portion of the body, wherein the first body portion is configured to at least substantially cover a first side of the first electronic component, and wherein the second plate comprises a second body portion configured as a relative thin plate forming a second portion of the body, wherein the second body portion is configured to at least substantially cover a second side of the first electronic component.

An example embodiment of a method of cooling electronic components is further disclosed, the method including: providing a plurality of heat spreaders, wherein each heat spreader comprises a first plate and a second plate, wherein the first plate has a first body portion configured to cover and correlate with at least a portion of a surface contour of a first side of a first electronic component and the second plate has a second body portion configured to cover and correlate with at least a portion of a surface contour of a second side of a second electronic component, and wherein at least one of an extending group consisting of: the first plate, the second plate, and combinations of the first plate and the second plate form an extending member that is configured to extend to and overlap with a cold plate. The method in an embodiment further includes positioning each of the plurality of heat spreaders so that: the first plate covers and forms a thermally conductive relationship with the first side of the first electronic component; the second plate covers and forms a thermally conductive relationship with the second side of the first electronic component; and the extending member extends to, overlaps with, and forms a thermally conductive relationship with the cold plate. In an approach the method further includes supplying liquid coolant to the cold plate; and providing an air flow so that air flows along and in contact with the plurality of heat spreaders and the cold plate.

An embodiment of a system for cooling multiple electronics components is also disclosed, the system including a plurality of heat spreaders. In a configuration, each heat spreader includes a first plate and a second plate. The first plate according to an arrangement has a first body portion configured to at least substantially cover, conform to an outer surface shape of, and form a thermally conductive relationship with a first side of a first electronic component. The second plate according to an arrangement has a second body portion configured to at least substantially cover, conform to an outer shape of, and form a thermally conductive relationship with a second side of the first electronic component. According to a configuration, at least one of the first plate has a first extension and the second plate has a second extension wherein at least one of an extension group consisting of: the first extension, the second extension, and combinations of the first extension and the second extension form an extending member extending to and overlapping with a portion of a cold plate arranged to cool a second electronics component. The extending member according to an embodiment further has a bottom surface configured to be in at least one of a relationship group consisting of: being in contact with the cold plate, being in a thermally conductive relationship with the cold plate, and combinations thereof.

The foregoing summary is illustrative only and is not intended to be in any way limiting. In addition to the illustrative aspects, implementations, and features described above, further aspects, implementations, and features will become apparent by reference to the drawings and the following detailed description. In the drawings, like reference numbers indicate identical or functionally similar elements.

### BRIEF DESCRIPTION OF THE DRAWINGS

FIG. 1 illustrates a perspective view of electronic components arranged in a portion of an electronics server.

FIG. 2 illustrates a perspective view of an example embodiment of a cooling system, e.g., a hybrid cooling system, arranged to cool multiple electronic components in, for example, an electronics server.

FIG. 3 illustrates a rear view of the cooling system of FIG. 2 arranged to cool multiple electronic components.

FIG. 4 illustrates a front view of the cooling system of FIG. 2 arranged to cool multiple electronic components.

FIG. 5 illustrates a top view of the cooling system of FIG. 2 arranged to cool multiple electronic components.

FIG. 6 illustrates an exploded view of the cooling system of FIG. 2 arranged to cool multiple electronic components.

FIG. 7 illustrates perspective view of an example embodiment of a heat spreader of a cooling system, e.g., a hybrid cooling system, arranged to cool multiple components, including for example a DIMM.

FIG. 8 illustrates a right-side view of the heat spreader of FIG. 7.

FIG. 9 illustrates a left-side view of the heat spreader of FIG. 7.

FIG. 10 illustrates a top view of the heat spreader of FIG. 7.

FIG. 11 illustrates an exploded view of the heat spreader of FIG. 7.

FIG. 12 is a flow chart of an example method of cooling multiple electronic components.

### DETAILED DESCRIPTION

### Overview

Cooling electronics components in electronics servers, e.g., AI servers, with increasing density of electronic components that use increasingly more power and generate increasingly more heat is increasingly complex and challenging. While liquid coolant systems have been developed, those systems cannot practicably be used for all the electronic components in electronics servers. Cooling smaller components, such as the NIC card, DIMM memory and storage, comes with its own sets of challenges. Space constraints in electronics servers present their own set of difficulties in cooling electronic components in electronics servers. There is a need to provide an effective system and method to move, e.g., remove, heat from smaller electronic components and/or devices having limited space to improve the efficiency of cooling, for example air cooling, in electronics servers, e.g., AI systems.

Described herein is a system, mechanism, product and/or method for cooling two adjacent electronic components, for example DIMMs and SSDs, in for example an electronics server, using a heat spreader, and in an embodiment a combination of one or more heat spreaders and a cold plate. In an embodiment, the one or more heat spreaders use a thermally conductive material, for example, a Copper-Diamond composite to effectively remove heat from one or more first electronic components, e.g., one or more DIMMs. In an arrangement, due to the high thermal conductivity of the heat spreader, heat from the first component, e.g., the DIMM, is effectively transported to a cold plate, located for example above one or more second electronic components, e.g., an adjacent SSD, to reduce and/or prevent overheating of the first electronic component. In an embodiment, the heat spreader dissipates heat through the cold plate attached to the second electronic components, e.g., an adjacent SSD, through thermal conduction as well as through convection, such as forced convection. In an embodiment the heat spreader includes optional fins. In an arrangement, the optional fins on the left and right side of the plurality of heat spreaders are arranged so that the fins complement each other (e.g., are offset) when placed in a DIMM bank.

In the following description, numerous specific details are set forth, such as particular structures, components, materials, dimensions, processing steps and techniques, in order to provide an understanding of the various implementations of the present application. However, it will be appreciated by one of ordinary skill in the art that the various implementations of the present application may be practiced without these specific details. In other instances, well-known structures or processing steps have not been described in detail in order to avoid obscuring the present application.

### Example Environment

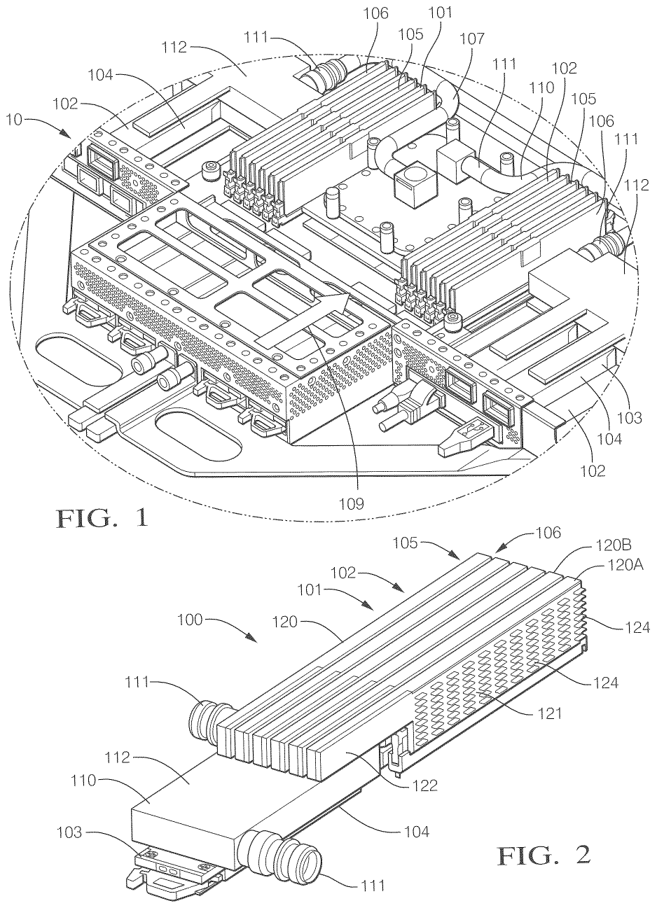

FIG. 1 illustrates a perspective view of a portion of an electronics server 10, e.g., an AI server, containing numerous electronics components 102. Some of the electronics components 102 include Solid State Drives (SSDs) 104 and Dual Inline Memory Modules (DIMMs) 106, among other electronics components 102 and connectors. A plurality of DIMMs 106 are arranged in the electronics server 10, for example, in DIMM bank 105. Electronics server 10 further includes a liquid coolant system 110 that includes one or more cold plates 112 and a plurality of conduits 117 for transporting a liquid coolant between cold plates 112, connectors 111, manifolds, and electronic components 102. There is a need to provide an effective system and method to move, e.g., remove, heat from smaller electronic components and/or devices having limited space to improve the efficiency of cooling, for example air cooling, in electronics servers 10, e.g., AI systems.

While the system, mechanism, product and/or method are described in connection with electronics servers, e.g., AI systems, the system, mechanism, product and/or method will have application to other environments and situations where cooling of electronic components is desirable. In addition, while the first electronic components 101 that are cooled by the system, mechanism, product, and/or method are shown and described as DIMMs 106 located in DIMM banks 105, it can be appreciated that other components can be cooled using the system, mechanism, product and/or method. Further, while the second component 103 for cooling in the system, mechanism, product and/or method is described in connection with SSDs 104, it can be appreciated that alternatively and/or additionally, other electronic components could be included.

### Example Implementation

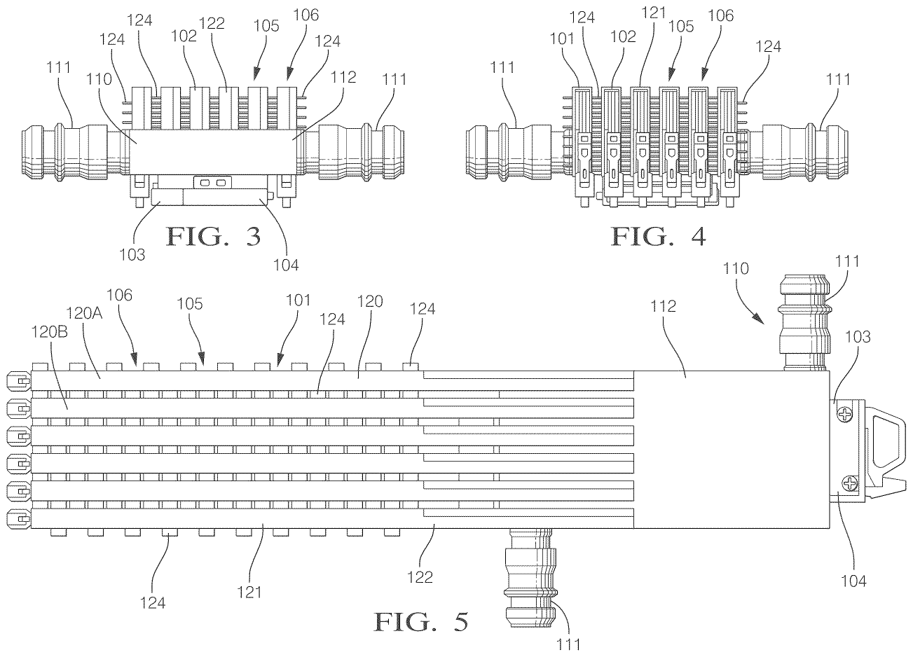

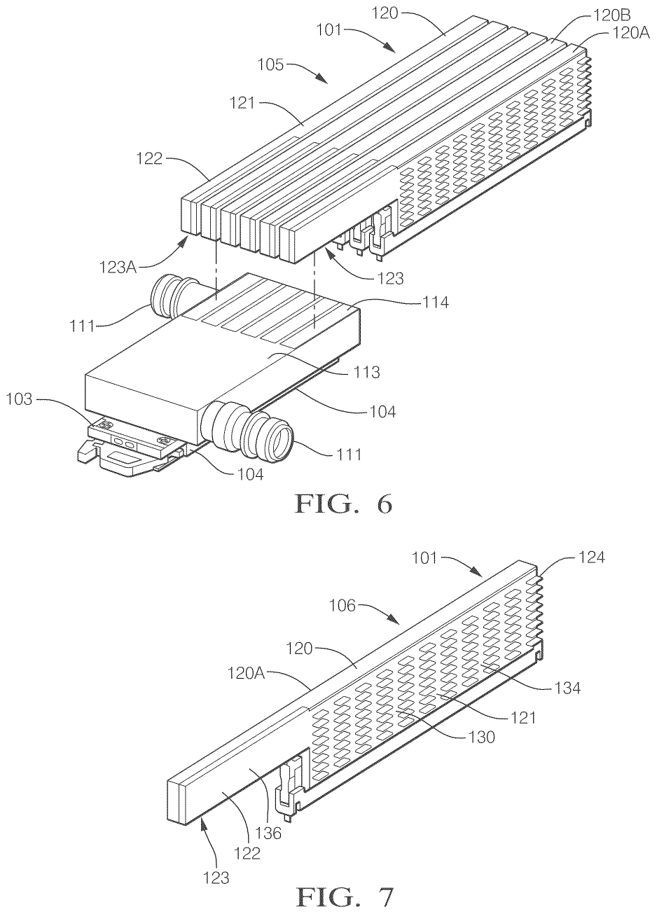

FIGS. 2-5 illustrate an example implementation of a cooling system 100 for cooling multiple electronic components 102, for example one or more SSDs 104 and a plurality of DIMMs 106 located in DIMM bank 105. FIG. 2 shows a top perspective view of the cooling system 100 including a plurality of DIMMs 106 arranged and configured in DIMM bank 105, heat spreader 120, cold plate 112, and one or more SSDs 104. FIGS. 3-4 illustrate respective rear and front views of cooling system 100, while FIG. illustrates a top view of cooling system 100. FIG. 6 shows an exploded view of DIMM bank 105 associated with, in contact with, and/or in a thermal transfer relationship with, e.g., a thermally conductive relationship with, a plurality of heat spreaders 120 and one or more SSDs 104 associated with, in contact with, and/or in a thermal transfer relationship with, e.g., a thermally conductive relationship with, cold plate 112.

Each of the DIMMs 106 in DIMM bank 105 is associated with, in contact with, and/or in a thermal transfer relationship with, e.g., a thermally conductive relationship with, heat spreader 120 formed of, for example, thermally conductive material. In an embodiment, heat spreader 120 includes Copper-Diamond thermally conductive composite material. As shown in FIGS. 2-6, each heat spreader 120 has an extending member 122 that extends beyond the body 121 of heat spreader 120 and/or the DIMM 106. The extending member 122 can also be formed of thermally conductive material, and in an embodiment formed of Copper-Diamond thermally conductive composite material. The extending member 122 extends to, is associated with, and is configured, sized, and/or arranged to be in contact with cold plate 112 of liquid coolant system 110. In an optional arrangement, extending member 122 extends to, is associated with, and can be configured, sized, and/or arranged to be in contact with a first Thermal Interface Material (TIM) 114 associated with and/or in contact with cold plate 112. In an embodiment, extending member 122 has a contact surface 123, e.g., bottom surface 123A, that is sized, shaped, and configured to match and be in contact with surface 113, e.g. top surface 113A, of cold plate 112, or respective first TIM 114. Extending member 122, including the contact surface 123, is configured, shaped, and arranged to be in a thermal transfer relationship with, e.g., a thermally conductive relationship with, cold plate 112.

Cold plate 112 is associated with and configured, sized, and/or arranged to be in contact with a second component 103, in an embodiment one or more SSDs 104. In an optional arrangement, cold plate 112, is associated with, and is configured, sized, and/or arranged to be in contact with a second TIM 115 (not shown) associated with and/or in contact with second component 103. Cold plate 112 has a surface, e.g., bottom surface 116 that is sized, shaped, and configured to correlate with, match, and/or be in contact with second component 103, e.g., one or more SSDs 104, or respective second TIM 115 associated with, in contact with, and/or in a thermal transfer relationship with, e.g., a thermally conductive relationship with, second component 103. Second component 103, e.g., SSDs 104, is configured, shaped, and arranged to be in a thermal transfer relationship with, e.g., a thermally conductive relationship, with cold plate 112.

In this manner, the cooling system 100, including the combination of one or more heat spreaders 120 and cold plate 112, is configured and/or arranged to cool a first electronic component 101, e.g., one or more DIMMs 106, and a second electronic component 103, e.g., one or more SSDs 104.

As shown in FIGS. 2-6, the plurality of DIMMs 106 in DIMM bank 105 are configured as rectangular-shaped plates inserted into sockets, and in the embodiment shown the rectangular shaped plate has a longer longitudinal length than its height, and the thickness of the rectangularly shaped plate is relatively thin compared to its length and/or height. Each DIMM 106 in DIMM bank 105 is laterally spaced apart from its adjacent DIMM 106. The plurality of DIMMs 106 can be arranged in DIMM Bank 105 to have a 9 mm pitch (lateral distance) between adjacent DIMMs 106. Other lateral distances between adjacent DIMMs 106, for example about 6 mm to about 12 mm, are contemplated.

Air flowing, shown by arrow 109 in FIG. 1, through the electronics server 10 facilitates and assists with cooling electronic components 102 in the electronics server 10. The lateral spacing between the DIMMs 106 in DIMM bank 105 permits air to flow between and/or around the one or more DIMMs 106 to facilitate and assist with cooling the DIMMs 106. Positioning and arranging thermally conductive material as heat spreader 120 about DIMMs 106 to at least partially, substantially entirely, and/or entirely surround and cover DIMMs 106 facilitates and increases cooling of DIMMs 106. In one or more embodiments, heat spreader 120 includes one or more fins 124 associated with and extending from thermally conductive material of the heat spreader 120.

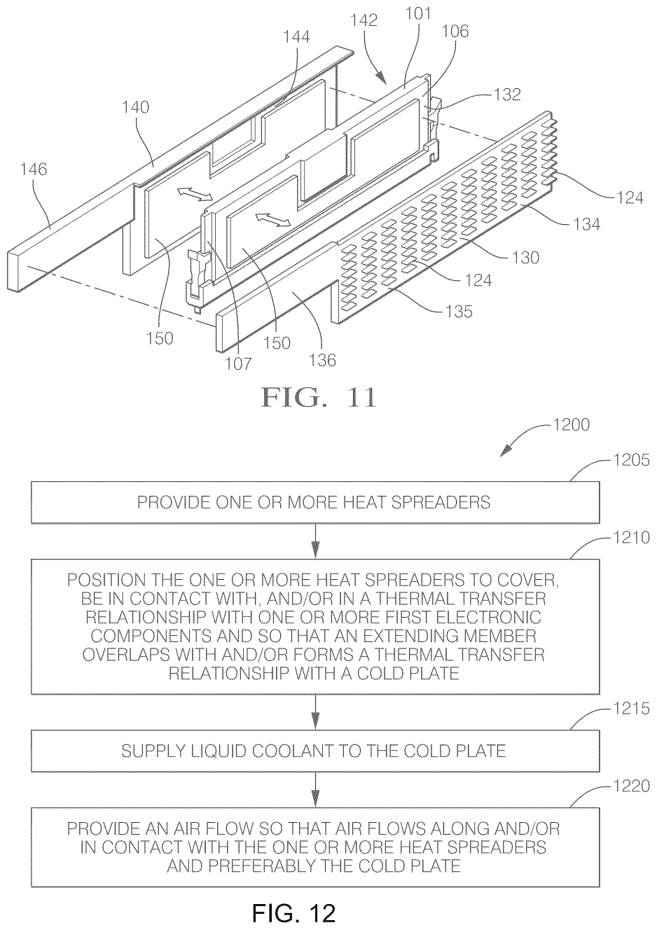

FIGS. 7-10 illustrate a first electronic component 101, e.g., a DIMM 106, surrounded by heat spreader 120, while FIG. 11 shows an exploded view of heat spreader 120 surrounding first electronic component 101, e.g. DIMM 106. As shown in FIG. 11, first plate 130 of heat spreader 120 is associated with, e.g., in contact with, and/or surrounds and covers the right side 132 of first electronic component 101, e.g., DIMM 106. First plate 130 includes a first body portion 134 that surrounds and/or covers (or substantially covers), and e.g., contacts, the right side 132 of first electronic component 101 and also includes a first extension 136 that extends beyond the periphery 107 of the first electronic component 101. First plate 130 can be configured as a relatively flat thin plate and forms the right (or first) side 135 of heat spreader 120. First body portion 134 and/or first extension 136, and e.g., both first body portion 134 and first extension 136, of first plate 130 are formed of thermally conducting material, and in an arrangement Copper-Diamond thermally conducting material. First body portion 134 and first extension 136 of first plate 130 can be formed as an integral component or can be separate parts, and first body portion 134 and first extension 136 may be formed of the same or different materials.

As shown in FIG. 11, second plate 140 is associated with, e.g., in contact with, and/or surrounds the left side 142 of first electronic component 101, e.g., DIMM 106. Second plate 140 includes a second body portion 144 that surrounds and/or covers, and e.g., contacts, the left side 142 of first electronic component 101 and also includes a second extension 146 that extends beyond the periphery 107 of the first electronic component 101. Second plate 140 in a configuration forms the left (or second) side 145 of heat spreader 120. Second body portion 144 and/or second extension 146, and e.g., both second body portion 144 and second extension 146, of second plate 140 are formed of thermally conducting material, and in an arrangement Copper-Diamond thermally conducting material. Second body portion 144 and second extension 146 of second plate 140 can be formed as an integral component or can be separate parts, and second body portion 144 and second extension 146 may be formed of the same or different materials.

In some embodiments, structures of the systems taught in the present disclosure may optionally include a separate and distinct thermal interface material 150. The thermal interface material, or TIM 150, may be provided on one surface or multiple surfaces of the subject system. In FIG. 11, a TIM 150 is provided between the first electronic component 101 and the first plate 130 and a TIM 150 is provided between the first electronic component 101 and the second plate 140.

It has been recognized by the inventors that the performance of electronic devices and even the lifetime of electronic devices can materially degrade when the devices are under continuous overheating, high temperatures, or large thermal stresses. TIM 150 may be formed of any suitable material to reduce these negative effects by enhancing the thermal coupling between the surfaces of the two or more structures TIM 150 adjoins. At each interface, thermal resistance exists and impedes heat dissipation. TIM 150 reduces the thermal resistance.

TIM 150 may take any suitable form. The inventors have recognized that various electronic structures may have different thermal expansion coefficients, particular elasticity (or lack thereof), non-planar topology, and other characteristics that make it difficult to increase thermal conductivity. To address these issues, TIM 150 may be arranged as a thermal paste, a thermal adhesive, a thermal epoxy, a thermally conductive pad, a thermal mat, a thermal tape, a phase change material (PCM), or some other material. TIM 150 may be malleable or rigid. TIM 150 may have one form (e.g., liquid) when applied and another form (e.g., solid) when deployed. In least some cases, TIM 150 is partially or completely formed from a metal.

In a configuration, the first plate 130 and second plate 140 in combination form heat spreader 120, and together substantially cover the sides, e.g., right side 132 and left side 142, of first electronic component 101, e.g., DIMM 106, as well as substantially cover the top surface of the first electronic component 101. In an arrangement, first plate 130 is snap fit to second plate 140, or otherwise connected to second plate 140 to substantially surround and/or cover, and e.g., be in contact with, the first electronic component 101 to effect heat transfer between the first electronic component 101 and heat spreader 120. The first plate 130 and the second plate 140 in an embodiment are both relatively thin, and in a configuration have the same thickness dimensions. For example, the first plate 130 and second plate 140 can fit over the sides 132, 142 of DIMMs 106 that are spaced 9 mm apart (e.g., the DIMM bank 105 has a 9 mm DIMM pitch), and still accommodate optional fins 124 described below.

The first extension 136 of the first plate 130 and the second extension 146 of the second plate 140 together form extending member 122 of heat spreader 120. A surface 123, e.g., bottom surface 123, of heat spreader 120 is configured to be associated with, in contact with, and/or e.g., matches a surface 113, e.g., top surface 113A of cold plate 112 and/or first TIM 114 of cold plate 112. Bottom surface 123 of heat spreader 120 which is configured to be associated with, in contact with, and/or correlates with and/or matches the contour of surface 113 of cold plate and/or or first TIM 114 of cold plate 112 is formed by at least one of first extension 136 of first plate 130 and/or second extension 146 of second plate 140, and e.g., is formed by both first extension 136 and second extension 146.

While heat spreader 120 has been described as being formed of two components, first plate 130 and second plate 140, it can be appreciated that heat spreader 120 can be formed as a single piece, or more than two pieces. In a configuration, heat spreader 120 can be formed as a single piece sleeve that fits over the first electronic component 101, e.g., DIMMs 104. In another arrangement, heat spreader 120 can be configured as only a single plate, for example only first plate 130 on one side of the first electronic component 101, e.g., DIMM 106. For example, heat spreader 120 can be first plate 130 associated with, in contact with, and/or forming a thermal transfer relationship with, e.g., a thermally conductive relationship with, first (right) side 132 of first component 101, e.g., DIMM 106. Alternatively, heat spreader 120 can be configured as only a single plate, for example only second plate 140 associated with, in contact with, and/or forming a thermal transfer relationship with, e.g., a thermally conductive relationship with, second (left) side 142 of first electronic component 101, e.g., DIMM 104. It can be appreciated that the shape, configuration, and size of heat spreader 120 can take many different forms and is not limited to the plate like structures shown and described. For example, if first electronic component 101 takes a different shape, size and form than the illustrated DIMMs 106, it can be appreciated that heat spreader 120 would also likely take a different shape, size, and form.

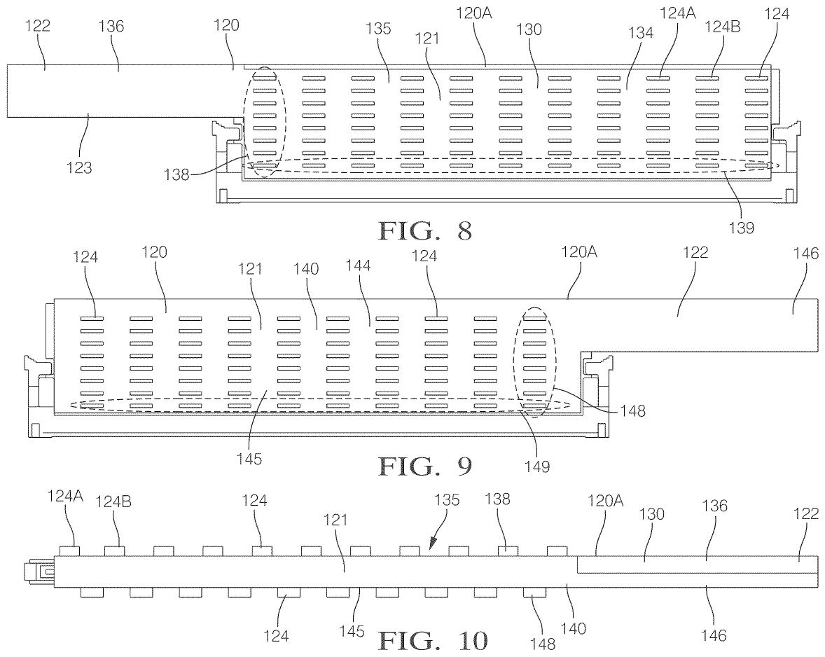

In an arrangement, optional fins 124 are associated with, formed on, and/or extend from the first side 135 and/or second side 145 of the heat spreader 120. The optional fins 124 on the first and/or second side 135, 145 of heat spreader 120 are arranged in an embodiment so that the fins 124 complement each other when placed about the DIMMs 106 in the DIMM bank 105. For example, as seen in FIG. 5, the top view of the DIMM bank 105, and FIGS. 8-10, the fins 124 on the first (right) side 135 of each heat spreader 120 are horizontally offset from the fins 124 on the second (left) side 145 of each heat spreader 120 so that when multiple DIMMs 106 are utilized in DIMM bank 105 the fins 124 on the second (left) side 145 of first heat spreader 120A are not horizontally aligned with the fins 124 on the first (right) side 135 of adjacent second heat spreader 120B. That is the columns 138 of fins 124 formed on the first (right) side 135 of first heat spreader 120A are not aligned with the columns 148 of fins 124 formed on the second (left) side 145 of heat spreader 120B.

Alternatively, or additionally, the fins 124 can be vertically offset. For example, as seen in FIGS. 3-4 and 8-9, the fins 124 on the first (right) side 135 of each heat spreader 120 are vertically offset from the fins 124 on the second (left) side 145 of each heat spreader 120 so that when multiple DIMMs 106 are utilized in DIMM bank 105 the fins 124 on the second (left) side 145 of first heat spreader 120A are not vertically aligned with the fins 124 on the first (right) side 135 of adjacent second heat spreader 120B. That is, the rows 139 of fins 124 formed on the first (right) side 135 of first heat spreader 120A are not (vertically) aligned with the rows 149 of fins 124 formed on the second (left) side 145 of heat spreader 120B.

In an arrangement the fins 124 are about 0.25 mm to about 0.35 mm thick, preferably about 0.3 mm thick; about 3 mm to about 7 mm long, preferably about 5 mm long, and about 2.0 mm to about 5.0 mm in height. The optional fins 124 in a further configuration are spaced about 2 mm to about 4 mm vertically apart, preferably about 3 mm vertically apart, and about 10 mm to about 14 mm horizontally apart in the flow direction, preferably about 12 mm apart in the flow direction. That is, in an embodiment, the front edge of a first fin 124A is about 10 mm to about 14 mm, preferably about 12 mm from the front edge of an adjacent second fin 124B.

It can be appreciated that fins 124 can take different shapes, sizes, and arrangements than illustrated and described herein. In this regard, where first electronic component 101, e.g., DIMMs 106, take on a different size, shape, and form, and are configured in different arrangements and positions (e.g., not arranged linearly alongside each other by a small distance), then the optional fins are likely to take different shapes, sizes and forms, and also configured in different arrangements.

### Example Installation

In an example installation, cooling system 100 is installed and implemented in an electronics server 10 similar to FIG. 1, where a plurality of heat spreaders 120 are arranged and configured to be associated with, in contact with, and in a thermal transfer relationship with, e.g., a thermally conductive relationship with, a plurality of DIMMs 106, where each DIMM has its own heat spreader 120. A plurality of DIMMs 106, in this case six DIMMs 106, each provided with its own heat spreader 120, are arranged in DIMM bank 105. The DIMMs 106, positioned in DIMM Bank 105, are arranged and positioned in the electronics server 10 so that air flows along the length of the DIMMs 106 and heat spreaders 120. The optional fins 124 are positioned and arranged on the heat spreader 120 so that the length of the fins 124 extends in the same direction as the length of the heat spreader 120 and also in the direction of air flow through the DIMMs 106 and/or electronics server 10.

In a configuration, the extending member 122 of heat spreader 120 extends toward and in contact with cold plate 112 as shown in FIGS. 2 and 5-6. Extending member 122 of each of heat spreader 120 has sufficient length to extend over top surface 113 of cold plate 112, and in an embodiment extending member 122 has sufficient length to extend over about half the length of the top surface 113 of the cold plate 112. While extending member 122 is shown as extending over about half the length of the top surface 113 of the cold plate 112, it can be appreciated that extending member 122 can extend over more or less of the length of the top surface 113 of the cold plate 112. For example, extending member 122 may extend over a range of 40% to 25% of the top surface 113 of the cold plate 112. Other lengths for extending member 122 of heat spreader 120, and other overlapping lengths between extending member 122 and cold plate 112 are contemplated.

Cold plate 112 is part of liquid cooling system 110 that includes one or more conduits 117 that transports liquid coolant. Liquid cooling system 110 can include one or more connectors, e.g., connectors 111, for connecting conduits 117 to cold plate 112.

In an embodiment, the cold plate 112 is positioned downstream of the air flow through the server 10. That is, the DIMM bank 105 is positioned upstream of the cold plate 112 so air flow 109 enters the DIMM bank 105; flows by and in contact with the body portions 134, 144 of first and second plates 130, 140 of the one or more heat spreaders 120 on the one or more DIMMs 106; flows by and in contact with the extending members 122 (e.g., the first extension 136 of the first plate 130 and the second extension 146 of the second plate) of the one or more heat spreaders 120 associated with, in contact with, and/or in a thermal transfer relationship with, e.g., a thermally conductive relationship with, the cold plate 112; and flows by, around and/or in contact with cold plate 112. Alternatively, the cold plate 112 is positioned upstream of the air flow 109 through the server 10. That is, the DIMM bank 105 is positioned downstream of the cold plate 112 so air flows by, in contact with and around cold plate 112; flows by, in contact with, and around extending members 122 of the one or more heat spreaders 120 on the one or more DIMMs; and enters the DIMM bank and flows by, in contact with the body portions 134, 144 of first and second plates 130, 140 of the one or more heat spreaders 120 on the one or more DIMMs 106.

In the example embodiment, the second component 103 that is cooled by cooling system 100 are SSDs 104. SSDs are components that are used for fast system boot-ups and high performance data storage. The Enterprise and Datacenter Standard Form Factor (EDSFF) specifications were developed to address the industry needs for simplicity and architect a new set of form factors for future data centers. The cooling system 100 in an embodiment is configured so that cold plate 112 is associated with, in contact with, and/or in a thermal transfer relationship with, e.g., a thermally conductive relationship with, E1.S SSDs. “E1.S” refers to a specific form factor of solid-state drive (SSD) known as “Enterprise and Datacenter Standard Form Factor (EDSFF) E1.S”, which is designed for high-density storage in data centers, particularly suited for applications like AI and machine learning due to its compact size, high performance, and efficient thermal management capabilities. E1.S SSDs are designed for flash memory chips and leverage PCIe® interface and NVMe protocol technologies.

In an embodiment, the second component 103 is an E1.S SSD, where the cold plate 112 is configured to cool the E1.S SSD. That is, the extending member 122 is configured and/or adapted to associate with, come into contact, and/or form a thermal transfer relationship with, e.g., a thermally conductive relationship with, the cold plate 112 arranged to cool the E1.S SSD. While the heat spreader 120 and cooling system 100 has been shown as working with a cold plate 112 configured for cooling E1.S SSDs, the cooling system 100 and heat spreader 120 can be configured to work with, be associated with, be in contact with, attach to, and/or form a thermal transfer relationship with, e.g., a thermally conductive relationship with, any cold plate and/or liquid tubes surrounding, adjacent to, and/or near DIMMs 106, or other first electronic component 101.

In the cooling system 100 heat from the first electronic component(s), e.g., DIMMs, is effectively transported by the heat spreader to the cold plate above the adjacent second electronic component(s), e.g. one or more SSDs. The heat spreader dissipates the heat through the cold plate that is attached to the second electronic component(s) through conduction as well as through convection, including in an embodiment by the optional fins attached to and/or extending from the heat spreader. The DIMMs in the cooling system 100 are hybrid cooled as heat from the DIMMs are removed by both liquid (via cold plate 112) and air (via heat spreader 120). Air flow through electronics server 10 can include one or more fans (not shown) to force air to move through electronics servers 10. Advantages of the described cooling system 100 include the ability to cool multiple different electronic components, e.g., SSDs (e.g., E1.S) and DIMMs, with a single cold plate thereby reducing space used in the chassis of a server; avoid having multiple liquid cooled components in series by combining the cooling of two components; and improving serviceability compared to traditional liquid cooled DIMMs.

### Example Use

FIG. 12 illustrates an exemplary flowchart in an embodiment illustrating and describing an example method 1200 of cooling a plurality of electronics components, for example in an electronics server, e.g., an AI server. While the method 1200 is described for the sake of convenience and not with an intent of limiting the disclosure as comprising a series and/or a number of steps, it is to be understood that the method 1200 does not need to be performed as a series of steps and/or the steps do not need to be performed in the order shown and described with respect to FIG. 12, but the method 1200 can be integrated and/or one or more steps can be performed together, simultaneously, or the steps can be performed in the order disclosed or in an alternate order.

At 1205 a plurality of heat spreaders are provided, for example as shown and described with reference to FIGS. 2-11. In an embodiment, each heat spreader can include and/or have a first plate and/or a second plate. In an arrangement the first plate has and/or includes a first body portion configured to cover, correlate with, and/or match at least a portion of, or substantially the entire, surface contour and/or shape of a first side of the first electronic component(s). In a further arrangement the second plate can include and/or have a second body portion configured to cover, correlate with, and/or match at least a portion of, or substantially the entire, surface contour and/or shape of a second side of the first electronic component(s). In a configuration, each heat spreader further includes and/or has an extending member that is configured to extend to and/or overlap with a cold plate. In a configuration at least one of an extending group consisting of the first plate, the second plate, and combinations of the first plate and second plate that include an extension portion that forms the extending member.

In one or more embodiments, the first plate, the second plate, and/or both the first and second plate have and/or include a plurality of fins. The plurality of fins in an embodiment are arranged and configured as shown in FIGS. 2-10 and as described above. In a further embodiment, the extending member is formed of a first extension integrally formed with and extending from the first body portion of the first plate and formed of a second extension integrally formed with and extending from the second body portion of the second plate. The extending member of each of the heat spreaders in one or more embodiments includes and/or has a bottom surface that overlaps with the cold plate wherein the bottom surface is configured to conform to, match, and/or contact a top surface of the cold plate.

At 1210 each of the plurality of heat spreaders are positioned so that: the first plate covers and/or forms a thermal transfer relationship with, for example a thermal transfer relationship with, e.g., a thermally conductive relationship with, the first side of the first electronic component(s); the second plate covers and/or forms a thermal transfer relationship with, for example a thermally conductive relationship with, the second side of the first electronic component(s). In a further embodiment, the extending member extends to, overlaps with, and/or forms a thermal transfer relationship with, for example a thermally conductive relationship with, the cold plate. In an embodiment, positioning each of the plurality of heat spreaders includes attaching each of the first plates with each corresponding second plate to form each of the plurality of heat spreaders.

At 1215 liquid coolant is supplied to the cold plate, and at 1220 an air flow is provided so that air flows along and in contact with the plurality of heat spreaders and with the cold plate. In a further arrangement, air is forced, for example by use of a fan, to flow along and in contact with the plurality of heat spreaders and the cold plate, while liquid coolant is supplied to the cold plate. In a further configuration, one or more second electronic components are provided in a thermal transfer relationship with, e.g., in a thermally conductive relationship with, the cold plate. In a further embodiment, the first electronic component is a DIMM and in an optional arrangement, each heat spreader is positioned about a DIMM such that the plurality of heat spreaders cover and/or form a thermal transfer relationship with, e.g., a thermally conductive relationship with, a plurality of DIMMs, wherein in a configuration the plurality of DIMMs are arranged in a DIMM bank, where in a further configuration each DIMM is laterally spaced apart from an adjacent DIMM by about 7 mm to about 12 mm, preferably about 9 mm. In a further arrangement, the cold plate is arranged to contact and/or be attached to one or more SSDs.

### EXAMPLES

Example 1: An apparatus that includes: a body formed of thermally conductive material configured to be in a first thermally conductive relationship with a first electronic component; and an extending member projecting from the body to extend to and overlap with a portion of a cold plate arranged to cool a second electronic component, the extending member further configured to be in a second thermally conductive relationship with the cold plate.
Example 2: The apparatus of Example 1, further including a plurality of fins that extend from at least one of the body or the extending member.
Example 3: The apparatus according to Example 2, wherein the plurality of fins only extend from the body.
Example 4: The apparatus according to any one of Examples 1-3, wherein the first electronic component is a Dual Inline Memory Module (DIMM) and the second electronic component is a Solid State Drive (SSD).
Example 5: The apparatus according to Example 4, wherein the SSD has an ES.1 form factor.
Example 6: The apparatus according to any one of Examples 1-5, wherein the body forms a sleeve that fits over the first electronic component.
Example 7: The apparatus according to any one of Examples 1-6, wherein the thermally conductive material is a copper-diamond composite.
Example 8: The apparatus according to anyone of Examples 1-7, further including one or more transfer interface materials between the cold plate and the heat spreader and in an arrangement one or more transfer interface materials between the cold plate and the second electronic component.
Example 9: The apparatus according to any one of Examples 1-8, wherein the apparatus includes or has a first plate and/or a second plate. In an arrangement the first plate includes a first body portion configured as a relative thin plate forming a first portion of the body, wherein the first body portion is configured to at least substantially cover a first side of the first electronic component. Alternatively, or additionally, the second plate includes a second body portion configured as a relative thin plate forming a second portion of the body, wherein the second body portion is configured to at least substantially cover a second side of the first electronic component.
Example 10: The apparatus according to Example 9, wherein at least one of the first plate or the second plate comprises an extension forming at least a portion of the extending member.
Example 11: The apparatus according to Example 9, wherein the first plate comprises a first extension forming a first portion of the extending member and the second plate comprises a second extension forming another portion of the extending member.
Example 12: The apparatus according to any one of Examples 9-11, wherein the first body portion is integral with the first extension and the second body portion is integral with the second extension.
Example 13: The apparatus according to any one of Examples 9-12, further comprising fins arranged and configured on the first plate and the second plate.
Example 14: The product according to Example 13, wherein the fins are arranged on the first plate in rows and columns and the fins are arranged on the second plate in rows and columns.
Example 15: The apparatus according to Example 14, wherein the rows of fins on the first plate are not aligned with the rows of fins on the second plate.
Example 16: The apparatus according to anyone of Examples 14-15, wherein the columns of fins on the first plate are not aligned with the columns of fins on the second plate.
Example 17: The apparatus according to any one of Examples 14-16, wherein the fins have a thickness of about 0.2 mm to about 0.4 mm, a length of about 3 mm to about 7 mm, and the rows are vertically spaced apart about 2 mm to about 4 mm and the columns are horizontally spaced apart about 10 mm to about 14 mm from a front edge of a first fin to a front edge of a second adjacent fin.
Example 18: A method of cooling electronic components including: providing a plurality of heat spreaders, wherein each heat spreader comprises a first plate and a second plate, wherein the first plate has a first body portion configured to cover, correlate with, and/or match at least a portion of a surface contour of a first side of a first electronic component, correlate with, and/or match the surface contour of substantially the entire first side of the first electronic component and the second plate has a second body portion configured to cover, correlate with, and/or match at least a portion of a surface contour of a second side of a second electronic component, cover, correlate with, and/or match the surface contour of substantially the entire second side of the first electronic component, and wherein at least one of an extending group consisting of: the first plate, the second plate, and combinations of the first plate and the second plate form an extending member that is configured to extend to and overlap with a cold plate; and positioning each of the plurality of heat spreaders so that: the first plate covers and forms a thermal transfer relationship with, e.g., in an embodiment a thermally conductive relationship with, the first side of the first electronic component; the second plate covers and forms a thermal transfer relationship with, e.g., in an approach a thermally conductive relationship with, the second side of the first electronic component; and the extending member extends to, overlaps with, and forms a thermal transfer relationship, e.g., in an arrangement a thermally conductive relationship with, the cold plate. In an approach the example method further includes supplying liquid coolant to the cold plate; and providing an air flow so that air flows along and in contact with the plurality of heat spreaders and the cold plate.
Example 19: The method according to example 18, further including forcing air to flow along and in contact with the plurality of heat spreaders and the cold plate, while liquid coolant is supplied to the cold plate.
Example 20: The method according to any one of examples 18-19, further including providing a second electronics component in a thermally conductive relationship with the cold plate.
Example 21: The method according to any one of examples 18-20, wherein each of the plurality of heat spreaders comprise a plurality of fins.
Example 22: The method according to any one of examples 18-21, wherein the extending member of each of the heat spreaders has a bottom surface that overlaps with the cold plate wherein the bottom surface is configured to conform to, correlate with, and/or match with at least a portion of a top surface portion of the cold plate, and in an arrangement the bottom surface is configured to conform to, correlate with, and/or match substantially the entirety of an overlapping area with the cold plate.
Example 23: The method according to any one of examples 18-22, further comprising attaching each first plate to each second plate to form each heat spreader.
Example 24: The method according to any one of examples 18-23, wherein the first electronic component is a DIMM and each heat spreader is positioned about a DIMM such that the plurality of heat spreaders cover and form a thermally conductive relationship with, a plurality of DIMMs, wherein the plurality of DIMMs are arranged in a DIMM bank, wherein each DIMM is laterally spaced apart from an adjacent DIMM by about 7 mm to about 12 mm, and the cold plate is attached to one or more SSDs.
Example 25: The method according to any one of examples 18-24, further including positioning the cold plate downstream from the plurality of heat spreaders so that the air flow first flows along and in contact with the plurality of heat spreaders before flowing along and in contact with the cold plate.
Example 26: The method according to any one of examples 18-24, further including positioning the cold plate upstream from the plurality of heat spreaders so that the air flow first flows along and in contact with the cold plate before flowing along and in contact with the plurality of heat spreaders.
Example 27: A system for cooling multiple electronic components, the system including a plurality of heat spreaders wherein each heat spreader includes: a first plate and a second plate, wherein, the first plate includes a first body portion configured to at least substantially cover, conform to at least a portion of an outer surface shape of, and/or form a thermally conductive relationship with a first side of a first electronic component; and the second plate includes a second body portion configured to at least substantially cover, conform to at least a portion of an outer shape of, and/or form a thermally conductive relationship with a second side of the first electronic component. In a configuration, at least one of the first plate includes a first extension and the second plate includes a second extension wherein at least one of the first extension, the second extension, and combinations of the first extension and the second extension form an extending member extending to and overlapping with a portion of a cold plate arranged to cool a second electronics component, the extending member further including a bottom surface configured to be in at least one of a relationship group consisting of: being in contact with the cold plate, being in a thermally conductive relationship with, the cold plate, and combinations thereof.
Example 28: The cooling system according to example 27, wherein the first plate is attached to the second plate to form each of the plurality of heat spreaders.
Example 29: The cooling system according to any one of examples 27-28, further including a plurality of fins extending from the first body portion and the second body portion of each heat spreader.
Example 30: The cooling system according to example claim 29, wherein the plurality of fins are configured in rows and columns extending from each of the first body portion and the second body portion of each heat spreader.
Example 31: The cooling system according to example 30, wherein at least one of: the rows of the plurality of fins extending from the first body portion and the rows of the plurality of fins extending from the second body portion are offset; the columns of the plurality of fins extending from the first body portion and the columns of the plurality of fins extending from the second body portion re offset; and combinations thereof are offset.
Example 32: The cooling system according to example 30, wherein the rows of the plurality of fins extending from the first body portion are vertically offset from the rows of the plurality of fins extending from the second body portion and the columns of the plurality of fins extending from the first body portion are horizontally offset from the columns of the plurality of fins extending from the second body portion.

### CONCLUSION

The terminology used herein is for the purpose of describing particular implementations only and is not intended to be limiting of this disclosure. As used herein, the singular forms “a”, “an” and “the” are intended to include the plural forms as well, unless the context clearly indicates otherwise. It will be further understood that the terms “includes”, “including”, “comprises” and/or “comprising,” when used in this specification, specify the presence of stated features, integers, steps, operations, elements, components, subsystems and/or groups but do not preclude the presence or addition of one or more other features, integers, steps, operations, elements, components, subsystems, and/or groups thereof. Further, the terms up, upper, down, lower, above, below, left, right, forward, rearward, first, second, third, and the like are intended to be understood in the context of the representations described and illustrated above so that a system, device, product, subsystem, and/or component may have such an orientation in reference to the frame or to various elements as supported by the frame or as illustrated in the drawing or figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various implementations were chosen and described in order to explain the principles of this disclosure and the practical application, and to enable others of ordinary skill in the art to understand this disclosure for various implementations with various modifications as are suited to the particular use contemplated.

What is claimed is:

1. An apparatus comprising:
a body formed of thermally conductive material configured to be in a first thermally conductive relationship with a first electronic component; and
an extending member projecting from the body to extend to and overlap with a portion of a cold plate arranged to cool a second electronics component, the extending member further configured to be in a second thermally conductive relationship with with the cold plate.

2. The apparatus according to claim 1, further comprising a plurality of fins that extend from at least one of the body, the extending member, and combinations thereof.

3. The apparatus according to claim 1, wherein the first electronic component is a Dual Inline Memory Module (DIMM) and the second electronic component is a Solid State Drive (SSD).

4. The apparatus according to claim 1, wherein the thermally conductive material is a copper-diamond composite.

5. The apparatus according to claim 1, wherein the body comprises a first plate and a second plate, wherein:
the first plate comprises a first body portion configured as a relative thin plate to at least substantially cover a first side of the first electronic component; and
the second plate comprises a second body portion configured as a relative thin plate to at least substantially cover a second side of the first electronic component.

6. The apparatus according to claim 5, wherein the extending member comprises a first extension forming a first portion of the extending member extending from the first body portion and a second extension forming another portion of the extending member extending from the second body portion.

7. The apparatus according to claim 6, wherein the first body portion is integral with the first extension and the second body portion is integral with the second extension.

8. The apparatus according to claim 5, further comprising fins arranged on the first plate and the second plate.

9. The apparatus according to claim 8, wherein the fins are arranged on the first plate in rows and columns and the fins are arranged on the second plate in rows and columns, and the rows of fins on the first plate are not aligned with the rows of fins on the second plate.

10. The apparatus according to claim 8, wherein the fins are arranged on the first plate in rows and columns and the fins are arranged on the second plate in rows and columns, and the columns of fins on the first plate are not aligned with the columns of fins on the second plate.

11. A method of cooling electronic components comprising:
providing a plurality of heat spreaders, wherein each heat spreader comprises a first plate and a second plate, wherein the first plate has a first body portion configured to cover and correlate with at least a portion of a surface contour of a first side of a first electronic component and the second plate has a second body portion configured to cover and correlate with at least a portion of a surface contour of a second side of a second electronic component, and wherein at least one extension extending from the first plate, the second plate, and combinations of the first plate and the second plate form an extending member that extends to and overlaps with a cold plate;
positioning each of the plurality of heat spreaders so that: the first plate covers and forms a thermally conductive relationship with the first side of the first electronic component; the second plate covers and forms a thermally conductive relationship with the second side of the first electronic component; and the extending member extends to, overlaps with, and forms a thermally conductive relationship with the cold plate;
supplying liquid coolant to the cold plate; and
providing an air flow so that air flows along and in contact with the plurality of heat spreaders and the cold plate.

12. The method according to claim 11, further comprising forcing air to flow along and in contact with the plurality of heat spreaders and the cold plate, while the liquid coolant is supplied to the cold plate.

13. The method according to claim 11, further comprising providing a second electronic component in a thermally conductive relationship with the cold plate.

14. The method according to claim 11, wherein each of the plurality of heat spreaders comprise a plurality of fins.

15. The method according to claim 11, wherein the first electronic component is a DIMM and each heat spreader is positioned about a DIMM such that the plurality of heat spreaders cover and form a thermally conductive relationship with a plurality of DIMMs, wherein the plurality of DIMMs are arranged in a DIMM bank, wherein each DIMM is laterally spaced apart from an adjacent DIMM, and the cold plate is attached to one or more SSDs.

16. The method according to claim 11, further comprising positioning the cold plate downstream from the plurality of heat spreaders so that the air flow first flows along and in contact with the plurality of heat spreaders before flowing along and in contact with the cold plate.

17. A system for cooling multiple electronic components, the system comprising a plurality of heat spreaders,
wherein each heat spreader comprises:
a first plate and a second plate, wherein,
the first plate comprises a first body portion configured to at least substantially cover, conform to an outer surface shape of, and form a thermally conductive relationship with a first side of a first electronic component; and
the second plate comprises a second body portion configured to at least substantially cover, conform to an outer shape of, and form a thermally conductive relationship with a second side of the first electronic component, and
wherein at least one of the first plate comprises a first extension and the second plate comprises a second extension that form an extending member extending to and overlapping with a portion of a cold plate arranged to cool a second electronics component, the extending member further comprising a bottom surface configured to be in a thermally conductive relationship with the cold plate.

18. The system according to claim 17, further comprising a plurality of fins extending from the first body portion and the second body portion of each heat spreader.

19. The system according to claim 18, wherein the plurality of fins are configured in rows and columns extending from each of the first body portion and the second body portion of each heat spreader.

20. The system according to claim 19, wherein at least one of:
an offset group including the rows of the plurality of fins extending from the first body portion and the rows of the plurality of fins extending from the second body portion are offset;
the columns of the plurality of fins extending from the first body portion and the columns of the plurality of fins extending from the second body portion are offset; and
combinations thereof are offset.
